(19) United States
(12) Patent Application Publication
(10) Pub. No.: US 2015/0372049 A1
(43) Pub. Date: Dec. 24, 2015

(54) METHOD OF MANUFACTURING SEMICONDUCTOR DEVICE

(71) Applicant: KABUSHIKI KAISHA TOSHIBA, Tokyo (JP)

(72) Inventors: Hideo TAKEYAMA, Oita Oita (JP); Masato FUKUMOTO, Oita Oita (JP); Shogo MATSUO, Oita Oita (JP)

(21) Appl. No.: 14/625,454

(22) Filed: Feb. 18, 2015

(30) Foreign Application Priority Data
Jun. 23, 2014 (JP) 2014-128664

(51) Int. Cl. H01L 27/146

(52) U.S. Cl. CPC H01L 27/14685; H01L 27/14698; H01L 27/14687; H01L 27/14643; H01L 27/14636

(57) ABSTRACT

A method of manufacturing a semiconductor device includes forming a first film on a semiconductor substrate. The semiconductor substrate includes metal impurities, which may cause defects in the semiconductor device. A second film is formed on the first film such that the first film is between the second film and the semiconductor substrate. The first film, the second film, and the semiconductor substrate are heated. During the heating, which may occur during various manufacturing steps of the semiconductor device, the metal impurities from the semiconductor substrate diffuse into the second film. After the heating, the first and second films are removed from the semiconductor substrate.

### CROSS-REFERENCE TO RELATED APPLICATION

This application is based upon and claims the benefit of priority from Japanese Patent Application No. 2014-128664, filed Jun. 23, 2014, the entire contents of which are incorporated herein by reference.

### FIELD

Embodiments described herein relate generally to a method of manufacturing a semiconductor device.

### BACKGROUND

In general, it is known that heavy metal impurities alter the properties and performance of solid-state imaging devices. When the heavy metal impurities are present in an active region of the solid-state imaging device, a defect in band gap is caused by the heavy metals. This defect causes a problem such as a leakage current or a white scratch artifact which appears as a bright area even when the imaging device is in a dark state. Thus, for example, in a manufacturing process of the solid-state imaging device, it is common to provide a gettering layer to capture heavy metal impurities. The gettering layer has a crystal grain boundary and crystal defects in the getter layer help to sequester the heavy metal impurities from the active device areas. As a method of manufacturing a semiconductor device using the gettering layer, a Poly-silicon Back Sealing (PBS) method is known.

### DESCRIPTION OF THE DRAWINGS

FIG. 1 to FIG. 7 depicts cross-sectional views of a semiconductor device illustrating a manufacturing process according to a first embodiment.

### DETAILED DESCRIPTION

In general, according to one embodiment, a method of manufacturing a semiconductor device includes forming a first film on a surface of a semiconductor substrate, forming a second film over the first film, heating the first film and the semiconductor substrate, and removing the first film and the second film.

A method of manufacturing a semiconductor device includes forming a first film on a semiconductor substrate. The semiconductor substrate includes metal impurities which may adversely affect the performance of the semiconductor device. A second film is formed on the first film such that the first film is between the second film and the semiconductor substrate. The first film, the second film, and the semiconductor substrate are heated. During heating metal impurities from the semiconductor substrate diffuse into the second film. The first and second films are removed from the semiconductor substrate.

Hereinafter, exemplary embodiments will be described with reference to drawings.

### First Embodiment

A method of manufacturing a semiconductor device according to a first embodiment using a solid-state imaging device as an example of a semiconductor device will be described. This exemplary embodiment provides a method by which heavy metal impurities levels may be reduced in a semiconductor substrate used in a manufacturing process of a semiconductor device.

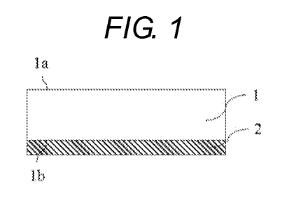

A manufacturing process of the semiconductor device according to the first embodiment will be described using FIGS. 1 to 7. FIGS. 1 to 7 are cross-sectional views illustrating a semiconductor device in a manufacturing process according to the first embodiment. A semiconductor device is, for example, a solid-state imaging device 200.

A solid-state imaging device 200 includes a first film 2 and a second film 3.

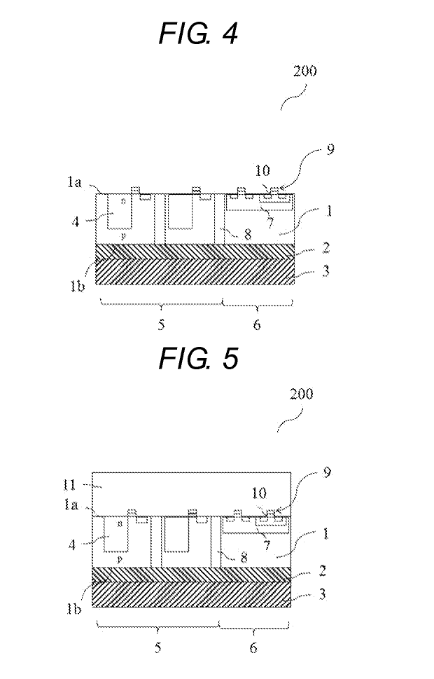

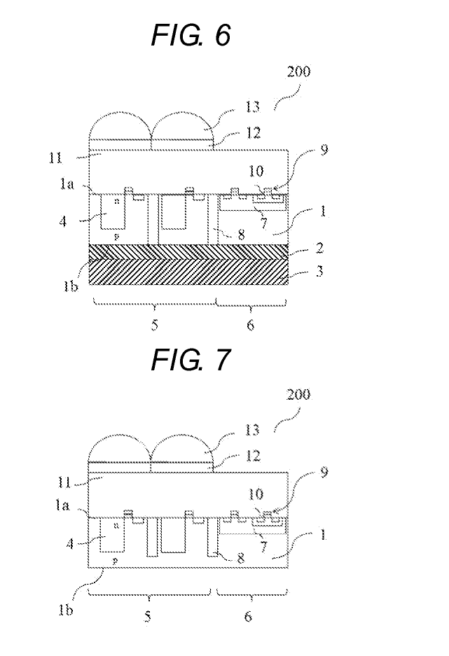

A solid-state imaging device 200 (see FIG. 3) has a pixel region 5 in which a photodiode 4 (see FIG. 4) is provided, and a peripheral region 6 (see FIG. 3) in which a circuit that processes a signal from the photodiode 4 or a circuit that controls an operation of the pixel region 5 is provided. The peripheral circuit 6 is provided so as to surround an outer periphery of the pixel region 5. These circuits in the peripheral region 6 may include a Metal Oxide Semiconductor (MOS) transistor 9 (see FIG. 3) and the like. The photodiode 4 and the MOS transistor 9 are provided in the semiconductor substrate 1. A wiring layer 11 (see FIG. 4) is provided on the semiconductor substrate 1. The wiring layer 11 includes, for example, an insulation film such as a silicon oxide film (SiO₂), a copper (Cu) wiring and the like which are formed by using, for example, a dual damascene method. The solid-state imaging device 200 further includes a color filter 12 and a microlens 13 (see FIG. 6).

The solid-state imaging device may in some embodiments be either a surface-illuminated type or a back-illuminated type.

Light, such as sunlight, is incident on the solid-state imaging device of a surface-illuminated type from a side (e.g., the uppermost surface in the up-down page direction in FIG. 7) on which the MOS transistor 9 and the wiring of the semiconductor substrate 1 are provided. On the other hand, light would be incident on the solid-state imaging device of a back-illuminated type from a side opposite to the side in which the MOS transistor 9 and the wiring of the semiconductor substrate 1 are provided. In each solid-state imaging device, light which is incident through the microlens 13 and the color filter 12 is converted into an electric signal by the photodiode 4. The electric signal produced by the photodiode 4 is then output to an external circuit via the transistor 9, the wiring(s), and the like.

A manufacturing process of the solid-state imaging device of a surface-illuminated type is described as an example; however, the present disclosure is also applicable to a manufacturing process for a solid-state imaging device of a back-illuminated type.

Hereinafter, a manufacturing process of the solid-state imaging device 200 according to the first embodiment will be described.

The semiconductor substrate 1 is made of silicon (Si), and includes a first surface 1a and a second surface 1b. The second surface 1b faces the first surface 1a—that is, the surfaces 1a and 1b are on opposite sides of the semiconductor substrate 1. First, a cleaning process is performed on the semiconductor substrate 1 so as to remove impurities adhering to a surface of the semiconductor substrate 1. In addition, a surface of the semiconductor substrate 1 may be naturally oxidized by being in contact with air, and a thin oxide film may be formed on a surface (or surfaces) of the semiconductor substrate 1. This thin oxide film is sometimes referred to as a “native oxide film.” In order to remove this thin oxide film, the surface of the semiconductor substrate 1 is cleaned with dilute hydrofluoric acid, for example.

Then, as illustrated in FIG. 1, a film forming apparatus (not shown) forms an oxide film 2 which is the first film 2 on the second surface 1b. In this example, the first film 2 is an oxide film; however, the first film 2 may be a film which suppresses a single crystallization of the second film 3 and allows heavy metal impurities in the semiconductor substrate 1 to move to the second film 3 via the first film 2. The first film 2 may be formed of, for example, alumina or silicon nitride. An oxide film 2 can be formed on the second surface of the semiconductor substrate 1 by increasing an oxygen concentration in a reactor using, for example, a Chemical Vapor Deposition (CVD) method or a Low Pressure Chemical Vapor Deposition (LPCVD) method as the film forming apparatus. Since the oxide film 2 is formed after removing a natural oxide film using hydrofluoric acid, in a case of the CVD method, a gas containing silicon atoms, such as silane (SiH₄), and an oxygen gas may be mixed with each other at elevated temperatures. The silane gas reacts at a temperature of 600 degrees to 650 degrees, and thereby the oxide film 2 is accumulated (deposited) on the second surface 1b. As the film forming apparatus, a plasma CVD method which forms an oxide film by reacting a silicon precursor material and oxygen by plasma may be used. It is preferable that a film thickness of the oxide film formed by the film forming apparatus be 1.5 nm or less. Moreover, it is preferable that the thickness of the formed oxide film be thicker than a film thickness of a native oxide film.

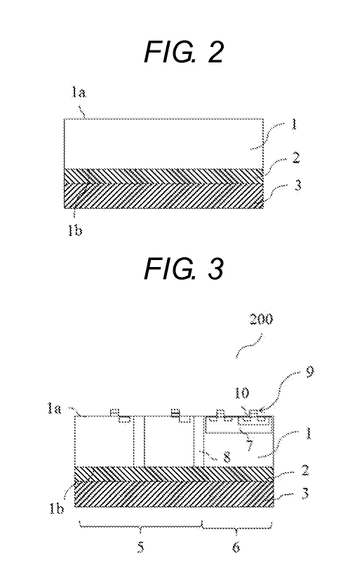

Then, as illustrated in FIG. 2, the second film 3 is formed on an exposed side of the oxide film 2. The second film 3 is a poly-silicon film 3 which has a gettering function. In a CVD apparatus, a poly-silicon is formed by allowing the silane gas (SiH₄) to flow and thermally decomposing the silane gas.

Then, as illustrated in FIG. 3, the pixel region 5 and the peripheral region 6 are formed by controlling an implantation of impurity ions in a predetermined region in the semiconductor substrate 1 using an implantation mask formed by photolithography. An element isolation region 8, which electrically isolates adjacent elements (e.g., photodiode and/or transistors), is formed at a predetermined position (or positions) in the pixel region 5 and the peripheral region 6. Element isolation region 8 may be formed by first forming a trench in the semiconductor substrate 1. Then, an insulation film is embedded in the trench to form the element isolation region 8. Alternatively, impurity ions (dopants) are implanted in the semiconductor substrate 1 in various regions so as to form regions in semiconductor substrate 1 having different conductivity types. Accordingly, a pnp junction and an npn junction, or a depletion region can be formed by the impurity regions formed in the semiconductor substrate. The element isolation region 8 suppresses current leakage between adjacent pixel regions 5.

Then, the MOS transistor 9 or a resistance element is formed in on the semiconductor substrate 1. A gate oxide film 10 of the MOS transistor 9 is formed by a thermal oxidation method, for example.

Then, as illustrated in FIG. 4, the impurities are ion-implanted into the pixel region 5. Then, for example, a p-type impurity region and an n-type impurity region are formed in the semiconductor substrate 1 by causing the implanted impurities to be thermally diffused into semiconductor substrate. The p-type impurity layer and the n-type impurity layer thus implanted function as the photodiode 4.

Then, as illustrated in FIG. 5, the wiring layer 11 is formed on the semiconductor substrate 1. The wiring layer 11 comprises a copper (Cu) wiring which is formed on an insulation film (not specifically depicted) such as a silicon oxide film (SiO₂) using, for example, a dual damascene method. In addition to copper, aluminum (Al) or tungsten (W), and the like may also be used for a wiring in the wiring layer 11.

As illustrated in FIG. 6, a color filter 12 is formed via an anti-reflection film (not specifically illustrated) on the wiring layer 11 in the pixel region 5 for each pixel. That is, an anti-reflection film may be disposed between the wiring layer 11 and the color filter 12. Furthermore, the microlens 13 is formed on the color filter 12 for each pixel.

As illustrated in FIG. 7, the oxide film 2 and the second film 3 are removed by using a Chemical Mechanical Polishing (CMP) method. Thus, the heavy metal impurities captured (gettered) by the second film 3 do not remain in the finished solid-state imaging device 200.

A removal of the oxide film 2 and the second film 3 may be performed after performing all heat treatments in the manufacturing process of the solid-state imaging device 200. An example of performing a heat treatment herein includes, for example, a film formation by the CVD method, a thermal diffusion after the implantation of impurity ions, a thermal oxidation when forming a gate oxide film, or the like.

As mentioned above, the solid-state imaging device 200 is completed by a manufacturing method according to the first embodiment.

Features in the method of manufacturing the solid-state imaging device 200, and operation and effects thereof will be described.

Heavy metal impurities such as aluminum (Al), copper (Cu), nickel (Ni) included in the semiconductor substrate 1 are captured by a crystal grain boundary or dangling bonds caused by crystal defects. Therefore, a capacity for capturing heavy metal impurities depends on a crystal surface area in a collection of crystals or alternatively the number of dangling bonds per crystal. The crystal surface area is a sum of surface areas for crystal grains with a crystal orientation. In this example, the second film 3 is polycrystalline, and is a poly-silicon film having a large number of crystal grain boundaries. Since the capability for capturing heavy metal impurities depends on a crystal surface area, a poly-silicon which has a large crystal surface area has a high capability of capturing heavy metal impurities. In general, a poly-silicon is single crystallized (converted to single crystal silicon) when it is heated while in contact with a surface of a single crystal material, such as while in contact with the semiconductor substrate 1 during various processing steps for forming semiconductor device elements (e.g., photodiodes and transistors). Since the crystal surface area of the poly-silicon becomes smaller due to single crystallization (conversion of poly-silicon into single crystal material), the capability of capturing heavy metal impurities is lowered. The heavy metal impurities which are not captured by the poly-silicon will remain in the semiconductor substrate 1, thereby forming a defect level in the band gap of the semiconductor substrate 1. Electrons are easily activated at the defect site, and may be activated by a little energy. For this reason, a problem of a “white scratch” in a dark state is caused.

Therefore, by forming the oxide film 2 between the semiconductor substrate 1 and the poly-silicon film 3, it is possible to prevent the poly-silicon in film 3 from adopting the plane orientation of the adjacent semiconductor substrate 1 during heating processes and converting from poly-silicon to a single crystalline material corresponding to the single crystalline material of the semiconductor substrate 1. Accordingly, since a crystal surface area of the poly-silicon is not reduced by the heat treatment process(es), the capability of capturing heavy metal impurities in the poly-silicon is not lowered. That is, the heavy metal impurities in the semiconductor substrate 1 may be captured by the poly-silicon, and thus, a concentration of the heavy metal impurities in the semiconductor substrate 1 is lowered.

When a film thickness of the oxide film 2 is thick, a movement of the heavy metal impurities from the semiconductor substrate 1 toward the poly-silicon may be interfered with. The heavy metal impurities in the semiconductor substrate 1 may not be sufficiently captured in the poly-silicon with a very thick oxide film thickness. As a result, concentration of heavy metal impurities would not be sufficiently reduced in the semiconductor substrate 1, and the heavy metal impurities would remain in an active region of the solid-state imaging device 200.

On the other hand, when the film thickness of the oxide film 2 is thin, a poly-silicon film 3 adjacent the semiconductor substrate 1 (even though nominally separated by oxide film 2) may be affected by heating during manufacturing steps and portions of the poly-silicon may convert to single crystalline material. As noted, when the poly-silicon becomes single crystal, a surface area of a crystal is reduced. Thus, it is not easy to sufficiently capture heavy metal impurities.

It is desirable that the film thickness of the oxide film 2 be formed from 0.6 nm to 1.5 nm based on the above considerations. With the film thickness of the oxide film 2 formed in the above range, the movement of the heavy metal impurities to the poly-silicon is not significantly interfered with, and a single crystallization of the poly-silicon by a heat treatments does not significantly occur. From the above, it is possible to improve a capability of the poly-silicon to capture heavy metal impurities from the semiconductor substrate 1.

The second film 3 is described as the poly-silicon in this example; however, amorphous silicon may be also used as the second film 3. The amorphous silicon film 3 may be poly-crystallized by a heat treatment in the manufacturing process of the solid-state imaging device 200, that is, the amorphous silicon converts to a poly-silicon upon the heat treatment step in the manufacturing process.

As described above, by manufacturing a solid-state imaging device in a manufacturing method according to the embodiment, the heavy metal impurities concentration in the semiconductor substrate 1 of the solid-state imaging device may be reduced. As a result, it is possible to suppress occurrence of a white scratch or a leakage current in the solid-state imaging device.

### Second Embodiment

Next, a method of manufacturing a semiconductor device according to a second embodiment will be described.

A method of manufacturing a semiconductor device according to the second embodiment is different from that of a semiconductor device according to the first embodiment in that the oxide film 2 is formed using a chemical solution. The method of manufacturing a semiconductor device according to the second embodiment is otherwise substantially the same as the method of manufacturing a semiconductor device according to the first embodiment except for the above point, such that a detailed description is omitted with like reference numerals given to the like portions.

First, a cleaning process is performed on the second surface 1b of the semiconductor substrate 1 so as to remove impurities adhering to the semiconductor substrate 1.

Then, for example, an RCA cleaning (a standard method) is performed. The RCA cleaning is performed in a following procedure. For example, the semiconductor substrate 1 is immersed into a heated chemical solution including hydrochloric acid and hydrogen peroxide at a ratio of 1 to 4. Then, in order to remove an oxide film on the second surface 1b of the semiconductor substrate 1, the second surface 1b of the semiconductor substrate 1 is cleaned with a dilute hydrofluoric acid (DHF), and then is cleaned with ultrapure water. Then, the semiconductor substrate 1 is immersed into a heated chemical solution including ammonia water and hydrogen peroxide at a ratio of 1 to 4 for about five minutes. Accordingly, for example, a protective oxide film 2 is formed on the semiconductor substrate 1.

Then, the semiconductor substrate 1, in which the oxide film is formed on the second surface 1b thereof, is inserted into, for example, a CVD apparatus, so that a poly-silicon is formed on the semiconductor substrate via the second surface 1b.

As described above, in the method of manufacturing a semiconductor device according to the second embodiment, the oxide film 2 is formed by a chemical solution (wet processing) after a natural oxide film (native oxide) is removed by a chemical solution, such that the oxide film 2 is different from the natural oxide film and is an oxide film which is intentionally formed. Moreover, it is possible to prevent heavy metal impurities and the like from being mixed into the semiconductor substrate 1 until the semiconductor substrate 1 is inserted into the film forming apparatus. Moreover, since a formation of the oxide film 2 is performed in a process of cleaning the semiconductor substrate 1, it is possible to shorten a time for forming the oxide film 2 compared to when the oxide film 2 is formed by the film forming apparatus, such as a chemical vapor deposition tool, as in the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a first film on a semiconductor substrate, the semiconductor substrate including metal impurities;
forming a second film on the first film such that the first film is between the second film and the semiconductor substrate;
heating the first film, the second film, and the semiconductor substrate such that metal impurities from the semiconductor substrate diffuse into the second film; and
removing the first and second films.

2. The method according to claim 1, further comprising:
forming a photodiode in the semiconductor substrate before removing the first and second films.

3. The method according to claim 1, further comprising:
forming a wiring layer on the semiconductor substrate, the wiring layer comprising an insulation film and a metal wiring before removing the first and second films.

4. The method according to claim 1, wherein the first film and the second film are formed using vapor phase processing.

5. The method according to claim 1, wherein the forming of the first film includes treating the semiconductor substrate with hydrofluoric acid, and then immersing the semiconductor substrate in a solution of hydrogen peroxide and ammonia water.

6. The method according to claim 1, wherein the first film is a silicon oxide film and the semiconductor substrate is single crystalline silicon.

7. The method according to claim 6, wherein the second film is one of poly-silicon and amorphous silicon.

8. The method according to claim 1, wherein the second film is one of poly-silicon and amorphous silicon.

9. A method of manufacturing a semiconductor device, comprising:
removing a native oxide layer from a surface of a semiconductor substrate having metal impurities;
after removing the native oxide layer, forming an oxide film on the surface of semiconductor substrate, the oxide film having a thickness greater than the native oxide layer;
forming a gettering film on the oxide film such that the oxide film is between the semiconductor substrate and the gettering film, the gettering film being one of amorphous silicon and poly-silicon;
heating the semiconductor substrate with the oxide film and the gettering film formed thereon; and
removing the gettering film and the oxide film from the semiconductor substrate by chemical mechanical polishing.

10. The method of claim 9, wherein the thickness of the oxide film is less than 1.5 nm.

11. The method of claim 9, further comprising:
before removing gettering film and the oxide film, forming a photodiode in the semiconductor substrate using ion implantation.

12. The method of claim 9, wherein the gettering film is poly-silicon.

13. The method of claim 9, wherein the gettering film is formed by chemical vapor deposition.

14. The method of claim 9, wherein the oxide film is formed using wet processing.

15. The method of claim 9, wherein the oxide film is formed using chemical vapor deposition.

16. The method of claim 9, wherein the semiconductor substrate is single crystal silicon.

17. A method of manufacturing a semiconductor device, comprising:
removing a native oxide layer from a surface of a substrate, the substrate being single crystal silicon and including metal impurities;
after removing the native oxide layer, forming a second film on the surface of the substrate, the second film being one of silicon oxide, alumina, and silicon nitride and having a thickness that is greater than 0.6 nm and less than 1.5 nm;
forming a first film on the second film, the first film being one of amorphous silicon and poly-silicon;
forming a photodiode in the substrate;
heating the substrate with the first and second films formed thereon; and
removing the first and second films using chemical mechanical polishing.

18. The method of claim 17, wherein the first film is formed as amorphous silicon and heating the substrate converts the first film to poly-silicon.

19. The method of claim 17, wherein the removing of the native oxide film and the forming of the second film are performed using wet processing.

20. The method of claim 17, wherein the forming of the second film and the forming of the first are performed by chemical vapor deposition.
